(19) United States
(12) Patent Application Publication
(10) Pub. No.: US 2012/0008408 A1
(43) Pub. Date: Jan. 12, 2012

(54) NON-VOLATILE MEMORY DEVICE AND OPERATING METHOD OF THE SAME

(76) Inventors: Ji-Hwan KIM, Gyeonggi-do (KR); Myung CHO, Gyeonggi-do (KR)

(21) Appl. No.: 13/177,888

(22) Filed: Jul. 7, 2011

(30) Foreign Application Priority Data
Jul. 7, 2010 (KR) 10-2010-0065392

(51) Int. Cl. G11C 16/10; G11C 16/04

(52) U.S. Cl. 365/185.19; 365/185.18

(57) ABSTRACT

A non-volatile memory device and an operation method of the same are provided. A method for operating a non-volatile memory device includes programming a plurality of memory cells based on a target voltage level, verifying threshold voltage levels of the plurality of memory cells based on a correction voltage level higher than the target voltage level and selecting a memory cell programmed lower than the correction voltage level, and programming the selected memory cell based on the correction voltage level.

### CROSS-REFERENCE TO RELATED APPLICATIONS

The present application claims priority of Korean Patent Application No. 10-2010-0065392, filed on Jul. 7, 2010, which is incorporated herein by reference in its entirety.

### BACKGROUND

1. Field

Exemplary embodiments of the present invention relate to a non-volatile memory device, and more particularly, to an operation method of a non-volatile memory device.

2. Description of the Related Art

In a general semiconductor memory device, 1-bit data is stored in one memory cell. However, in a non-volatile memory device such as a NAND flash, more than 1-bit, e.g., 2-bit, data is stored in one memory cell so as to increase the storage capacity of the memory device and the integration degree of the memory device.

In a non-volatile memory, the threshold voltage of a memory cell is changed depending on data stored in the memory cell. For example, in a case that 1-bit data is stored in the memory cell, it is decided that data ‘1’ is stored in the memory cell when the threshold voltage is lower than 0V, and it is decided that data ‘0’ is stored in the memory cell when the threshold voltage is higher than 0V.

FIG. 1 illustrates an ideal distribution of the threshold voltages of memory cells when 2-bit data is stored in the each memory cell.

Referring to FIG. 1, if the level of the threshold voltage of the memory cell is lower than PV1, it is decided that data ‘11’ is stored in the memory cell. If the level of the threshold voltage of the memory cell is between PV1 and PV2, it is decided that data ‘01’ is stored in the memory cell. If the level of the threshold voltage of the memory cell is between PV2 and PV3, it is decided that data ‘00’ is stored in the memory cell. If the level of the threshold voltage of the memory cell is PV3 or higher, it is decided that data ‘10’ is stored in the memory cell.

FIG. 1 illustrates a case that a non-volatile memory has an ideal distribution of the threshold voltages of the memory cells as the result of a program operation. However, a non-volatile memory may have under-programmed cells (such as, memory cells programmed slower than general memory cells and memory cells programmed with a verification level lower than an original verification level because bouncing occurs on ground voltage level due to transient cell current generated in a verification operation). Therefore, the non-volatile memory may actually have a distribution of the threshold voltages illustrated in FIG. 2.

Referring to FIG. 2, some of the memory cells having the data ‘01’ may have a threshold voltage lower than PV1, some of the memory cells having the data ‘00’ may have a threshold voltage lower than PV2, and some of the memory cells having the data ‘10’ may have a threshold voltage lower the PV3.

If under-programmed cells having a threshold voltage lower a level corresponding to their data exist as described above, a failure may occur where wrong data is detected in a read operation.

### SUMMARY

An embodiment of the present invention is directed to a non-volatile memory device and a method for operating the same, which prevents the occurrence of under-programmed cells.

In accordance with an embodiment of the present invention, an operation method of a non-volatile memory device includes programming a plurality of memory cells based on a target voltage level; verifying threshold voltage levels of the plurality of memory cells based on a correction voltage level higher than the target voltage level and selecting a memory cell programmed lower than the correction voltage level among the memory cells; and programming the selected memory cell to the correction voltage level.

In accordance with another embodiment of the present invention, an operation method of a non-volatile memory device includes programming a plurality of memory cells based on a target voltage level; reading the plurality of memory cells based on a first correction voltage level lower than the target voltage level and a second correction voltage level higher than the target voltage level; and programming a memory cell of which a threshold voltage is higher than the first correction voltage level and lower than the second correction voltage level, among the plurality of memory cells, based on the second correction voltage level.

In accordance with yet another embodiment of the present invention, a non-volatile memory device includes a plurality of memory cells; and at leas one circuit configured to program the plurality of memory cells. In the non-volatile memory device, at least one circuit programs the plurality of memory cells based on a target voltage level, verifies threshold voltage levels of the plurality of memory cells based on a first correction voltage level higher than the target voltage level, selects a memory cell programmed lower than the first correction voltage level among the memory cells, and program the selected memory cell based on the first correction voltage level.

### BRIEF DESCRIPTION OF THE DRAWINGS

FIG. 1 is a view illustrating an ideal distribution of the threshold voltages of memory cells when 2-bit data is stored in the memory cell.

FIG. 2 is a view illustrating a distribution of the threshold voltages when a non-volatile memory has under-programmed cells.

FIG. 3 is a block diagram illustrating a non-volatile memory in accordance with an embodiment of the present invention.

FIG. 4 is a flowchart illustrating a method for operating a non-volatile memory in accordance with an embodiment of the present invention.

FIGS. 5A and 5B illustrates a distribution of the threshold voltages based on the method of FIG. 4.

FIG. 6 is a flowchart illustrating a method for operating a non-volatile memory in accordance with another embodiment of the present invention.

FIGS. 7A and 7B illustrates a distribution of the threshold voltages based on the method of FIG. 6.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

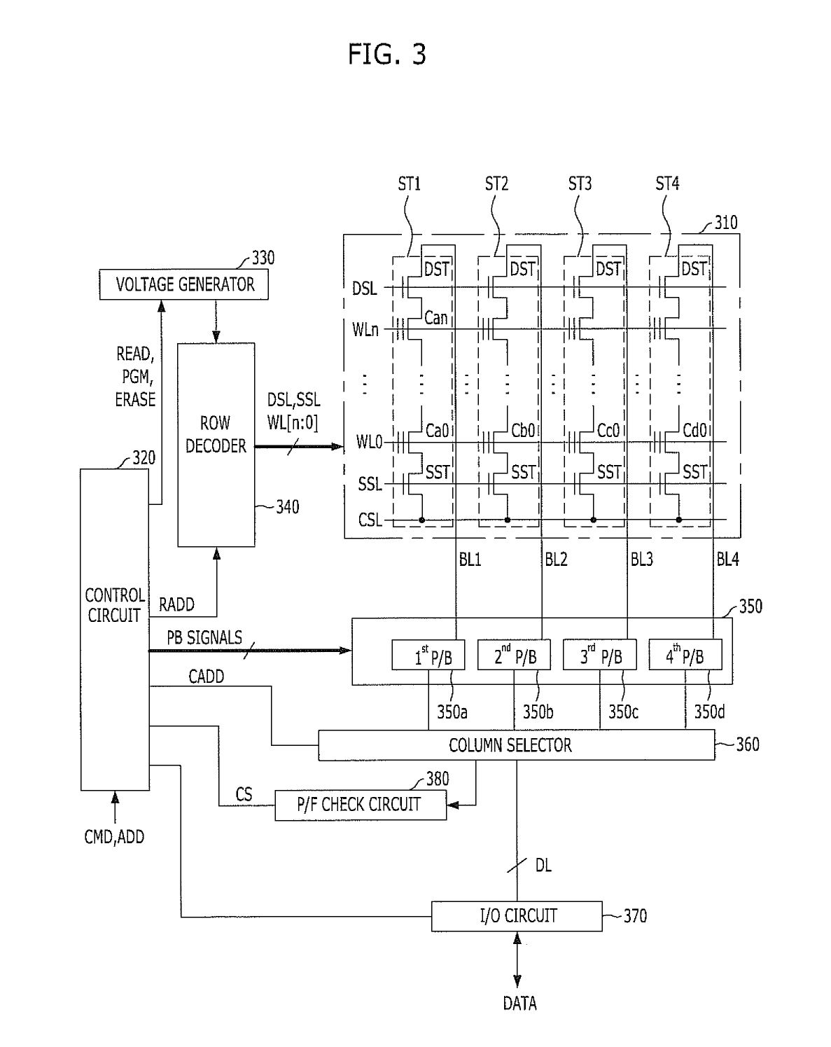

FIG. 3 is a block diagram illustrating a non-volatile memory in accordance with an embodiment of the present invention.

Referring to FIG. 3, the non-volatile memory includes a memory array 310, a control circuit 320, a voltage generator 330, a row decoder 340, a page buffer group 350, a column selector 360, an input/output (I/O) circuit 370, and a pass/fail (P/F) check circuit 380.

The memory array 310 includes a plurality of memory blocks. In FIG. 3, one of the memory blocks is shown. Each of the memory blocks is composed of a plurality of pages. Each of the pages is composed of a plurality of memory cells. In the non-volatile memory, an erase operation is performed on the basis of the memory block, and a read operation and a program operation are performed on the basis of the page.

Meanwhile, each of the memory blocks includes a plurality of memory strings. In FIG. 3, four ST1 to ST4 of the memory strings are shown. Each of the memory strings, e.g., the memory string ST1, is composed of a source select transistor SST having a source connected to a common source line CSL, a plurality of memory cells Ca0 to Can, and a drain select transistor DST having a drain connected to a bit line BL1. A gate of the source select transistor SST is connected to a source select line SSL, and gates of the memory cells Ca0 to Can are connected to word lines WL0 to WLn, respectively. A gate of the drain select transistor DST is connected to a drain select line DSL. The memory strings ST1 to ST4 are connected between the common source line CSL and respective bit lines BL1 to BL4.

The control circuit 320 outputs a program operation signal PGM, read operation signal READ or erase operation signal ERASE in response to a command signal, and outputs control signals PB SIGNALS for controlling page buffers 350a to 350d included in the page buffer group 350 depending on the operation to be performed. The control circuit 320 outputs row and column address signals RADD and CADD in response to an address signal ADD. The control circuit 320 checks whether or not the threshold voltages of memory cells selected in response to a check signal CS outputted from the P/F check circuit 380 are increased up to at least a target voltage, thereby controlling subsequent operations. The algorithm for a program, read or erase operation may be changed depending on how the control circuit 320 controls circuits in the non-volatile memory.

A voltage supply circuit supplies operation voltages for the program, erase, or read operation of the memory cells to the strings ST1 to ST4 of a selected memory block in response to the signal READ, PGM, ERASE, or RADD of the control circuit 320. The voltage supply circuit includes the voltage generator 330 and the row decoder 340.

The voltage generator 330 transfers operation voltages for programming, reading, or erasing the memory cells to the row decoder 340 in response to the operating signals READ, PGM, and ERASE that are internal command signals of the control circuit 320.

The row decoder 340 transfers the operation voltages generated from the voltage generator 330 to the strings ST1 to ST4 of a memory block selected from the memory blocks of the memory array 310 in response to the row address signals RADD of the control circuit 320. That is, the operation voltages are applied to lines DSL, WL[0:n], and SSL of the selected memory block.

The page buffer group 350 includes the page buffers 350a to 350d respectively connected to the bit lines BL1 to BL4. The page buffer group 350 applies voltages used for storing data in memory cells Ca0, Cb0, Cc0 and Cd0 to the bit lines BL1 to BL4 in response to the control signals PB SIGNALS of the control circuit 320. Specifically, for the program, erase, or read operation of the memory cells Ca0, Cb0, Cc0, and Cd0, the page buffers 350a to 350d pre-charge the bit lines BL1 to BL4 or latch data corresponding to the levels of threshold voltages of the memory cells Ca0, Cb0, Cc0, and Cd0 detected based on changes in voltages of the bit lines BL1 to BL4, respectively. That is, the page buffer group 350 adjusts voltages of the bit lines BL1 to BL4 based on data stored in the memory cells Ca0, Cb0, Cc0, and Cd0 and detects data stored in the memory cells Ca0, Cb0, Cc0, and Cd0.

The column selector 360 selects the page buffers 350a to 350d in response to the column address signal CADD outputted from the control circuit 320.

The I/O circuit 370 transfers data to the column selector 360 under a control of the control circuit 320 so as to input data inputted from the outside of the non-volatile memory to the page buffers 350a and 350d. If the column selector 360 sequentially inputs the transferred data to the page buffers 350a to 350d, each of the page buffers 350a to 350d stores the inputted data in an internal latch. The I/O circuit 370 outputs the data transferred from the page buffers 350a to 350d through the column selector 360 to the outside of the non-volatile memory.

The P/F check circuit 380 checks whether or not the threshold voltages of the memory cells selected in a program verifying operation performed after performing a program operation for applying a program voltage Vpgm to the selected word lines are all increased to at least the target voltage so as to store data in the memory cells, i.e., to increase the threshold voltages of the selected memory cells. The P/F check circuit 380 outputs the check signal CS to the control circuit 320 based on the checked result.

The control circuit 320 adjusts the level of a program voltage applied to a word line selected in the program operation of the memory cells, and controls the voltage generator 330 so as to selectively apply the verified voltages to the selected word line in the program verifying operation. The control circuit 320 may control the voltage generator 330 in response to the check signal CS of the P/F check circuit 380.

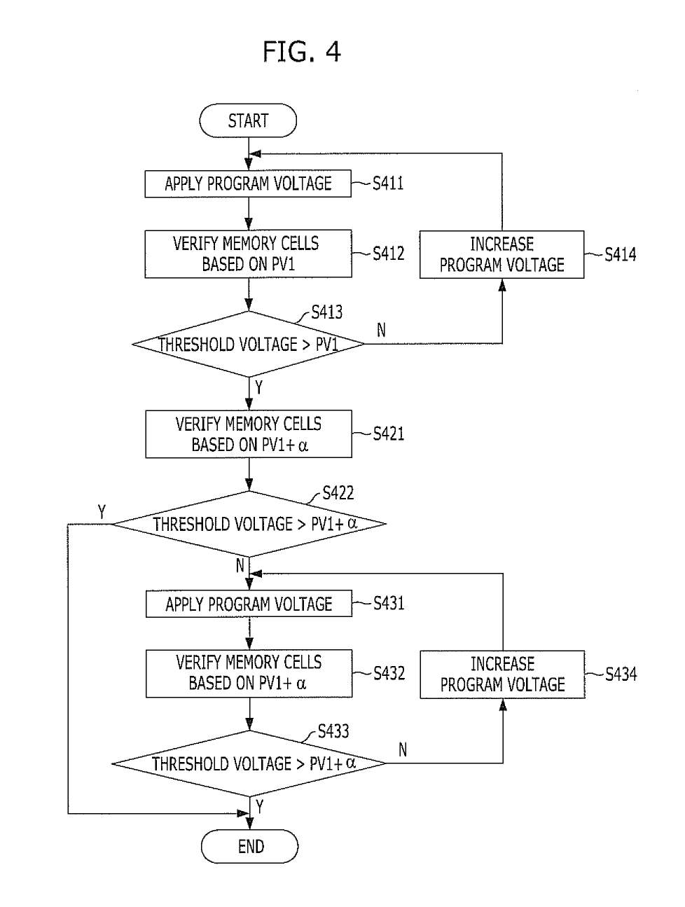

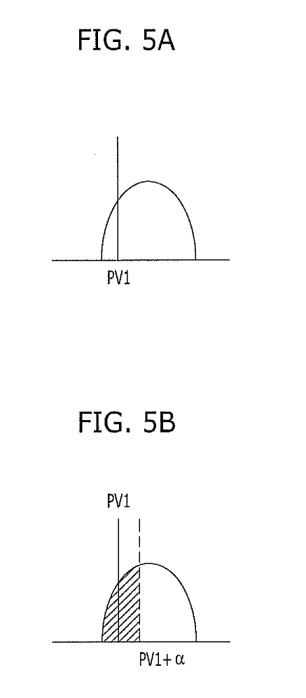

FIG. 4 is a flowchart illustrating a method for operating a non-volatile memory in accordance with an embodiment of the present invention. FIGS. 5A and 5B illustrate a distribution of the threshold voltages based on the method of FIG. 4.

Referring to FIG. 4, the method in accordance with the embodiment of the present invention includes programming a plurality of memory cells to have a target level PV1 (S411 to S414); verifying the plurality of memory cells based on a correction level PV1+α higher than the target level PV1 and selecting a memory cell under-programmed lower than the correction level PV1+α (S421 and S422); and programming the selected memory cell to have the correction level PV1+α (S431 to S434).

At the steps S411 to S414, a program operation is performed based on the target level PV1 using an incremental step pulse program (ISPP) method. Specifically, a program voltage is applied (S411), and a verify operation is performed on whether or not the level of the threshold voltage of the memory cell exceeds the target level PV1 (S412). If the verify operation is not completed (S413), the program voltage is increased (S414), and the increased program voltage is again applied (S411).

At the steps S411 to S414, the program operation is performed based on the target level PV1. However, even after the steps S411 to S414 are completed, memory cells of which threshold voltages have the voltage level PV1 or lower may exist as illustrated in FIG. 5A, e.g., a slow cell and an under-programmed cell due to source line bouncing.

At the steps S421 and S422, verification for the memory cells is performed based on the correction level PV1+α higher than the target level PV1. As the verification result, memory cells having the threshold voltages lower than the correction level PV1+α are selected (S422), so as to perform subsequent steps (S431 to S434). The memory cells distributed in the area of diagonal lines in FIG. 5B may be the selected memory cells on which the subsequent steps (S431 to S434) are performed.

At the step S431 to S434, a program operation is again performed, based on the correction level PV1+α, on the memory cells (memory cells in the area of the diagonal lines in FIG. 5B) selected at the steps S421 and 422. Specifically, a program voltage is applied (S431), and a verify operation is performed on whether or not the level of the threshold voltage of the memory cell exceeds the correction level PV1+α (S432). If the verify operation is not completed (S433), the program voltage is increased (S434), and the increased program voltage is again applied (S431). Since the threshold voltage of a memory cell under-programmed is increased at the steps S431 to S434, the under-programmed memory cell no longer exists in the non-volatile memory.

At the steps S411 to S414 and the steps S431 to S434, all the program operations are performed using the ISPP method. However, at the steps S431 to S434, the program operation is performed to increase only the threshold voltage of the under-programmed memory cell, and therefore, an incremental step of a program pulse in the ISPP method may be set smaller at the step S434 than at the step S414.

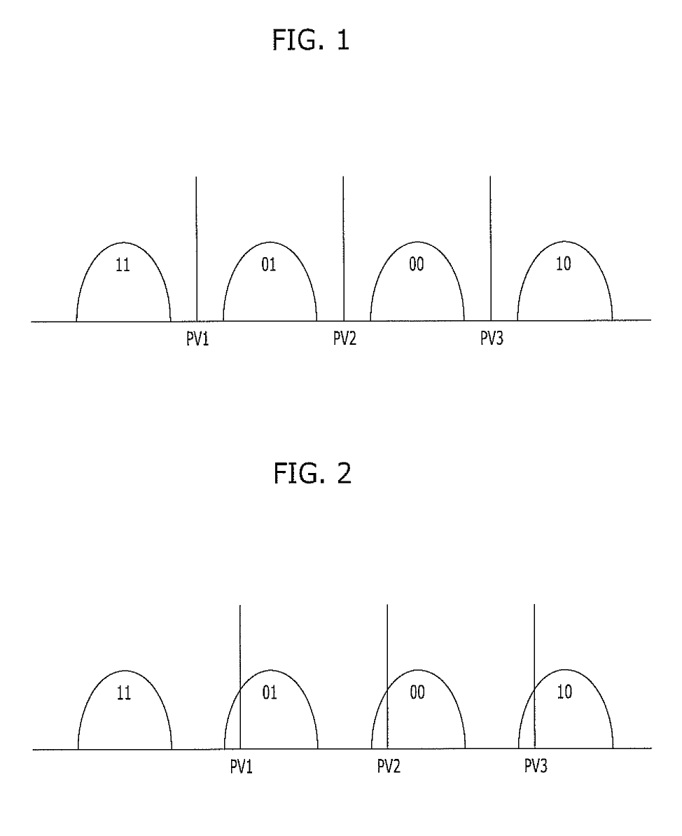

The method for preventing under-programmed memory cells when programming memory cells based on the target level PV1 has been described in the embodiment described above. However, it will be apparent that the method of FIG. 4 may be used to program memory cells based on a target level PV2, PV3 (see FIG. 1), or the like.

Since the correction level PV1+α is a voltage level used to select memory cells under-programmed lower than the target level PV1, the difference a between the correction level PV1+α and the target level PV1 may be preferably set to 20% or less of the difference between the voltage levels PV1 and PV2.

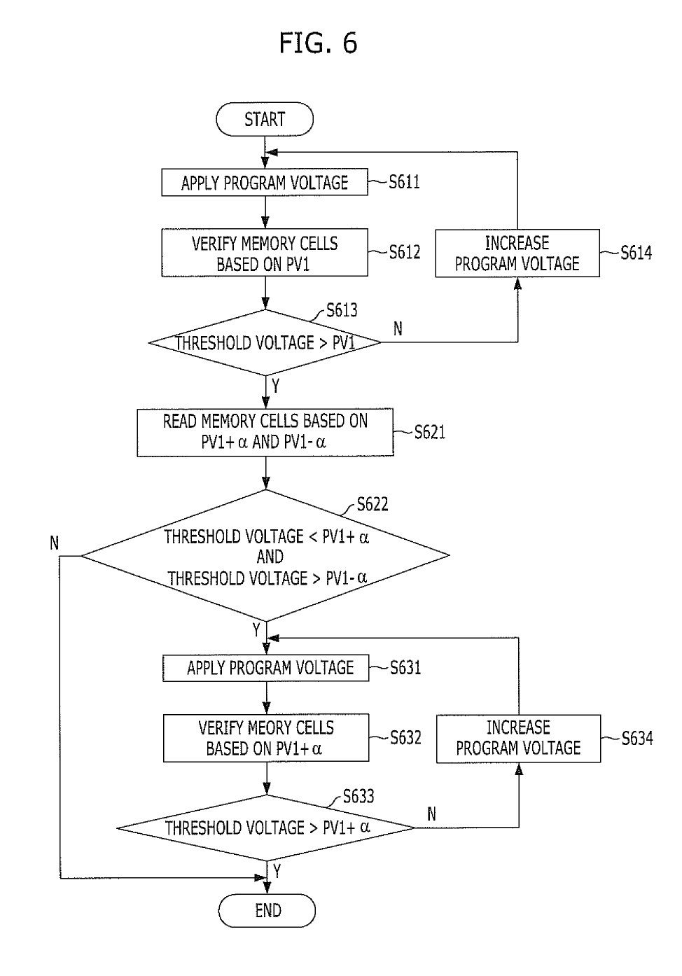

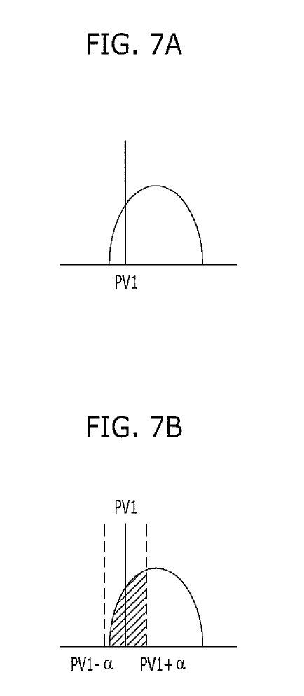

FIG. 6 is a flowchart illustrating a method for operating a non-volatile memory in accordance with another embodiment of the present invention. FIGS. 7A and 7B illustrate a distribution of the threshold voltages based on the method of FIG. 6.

Referring to FIG. 6, the method in accordance with the embodiment of the present invention includes programming a plurality of memory cells based a target level PV1 (S611 to S614); reading the plurality of memory cells based on a first correction level PV1−α lower than the target level PV1 and a second correction level PV1+α a higher than the target level PV1 (S621 and S622); and programming, based on the second correction level PV1+α, a memory cell having the threshold voltage higher than the first correction level PV1−α and lower than the second correction level PV1+α among the plurality of memory cells (S631 to S634).

At the steps S611 to S614, a program operation is performed based on the target level PV1 using the ISPP method. Specifically, a program voltage is applied (S611), and a verify operation is performed on whether or not the level of the threshold voltage of the memory cell exceeds the target level PV1 (S612). If the verify operation is not completed (S613), the program voltage is increased (S614), and the increased voltage is again applied (S611).

At the steps S611 to S614, the program operation is performed based on the target level PV1. However, even after the steps S611 to S614 are completed, memory cells of which threshold voltages have the voltage level PV1 or lower may exist as illustrated in FIG. 7A, e.g., a slow cell and an under-programmed cell due to source line bouncing.

At the steps S621 and S622, a read operation is performed based on the first correction level PV1−α and the second correction level PV1+α (S621), and memory having the threshold voltages higher than the first correction level PV1−α and lower than the second correction level PV1+α are selected (S622), so as to perform subsequent steps (S631 to S634). The memory cells distributed in the area of diagonal lines in FIG. 7B may be the selected memory cells on which the subsequent steps (S631 to S634) are performed.

At the steps S631 to S634, a program operation is again performed, based on the second correction level PV1+α, on the memory cells (memory cells in the area of the diagonal lines in FIG. 7B) selected at the steps S621 and 622.

At the steps S611 to S614 and the steps S631 to S634, all the program operations are performed using the ISPP method. However, at the steps S531 to S534, the program operation is performed to increase only the threshold voltage of the under-programmed memory cell, and therefore, an incremental step of a program pulse in the ISPP method may be set smaller at the step S634 than at the step S614.

The method for preventing under-programmed memory cells when programming memory cells based on the target level PV1 has been described in the embodiment described above. However, it will be apparent that the method of FIG. 6 may be used to program memory cells based on a target level PV2, PV3, or the like.

The difference between the first correction level PV1−α and the target level PV1 and the difference between the second correction level PV1+α and the target level PV1 may be preferably set to 20% or less of the difference between the voltage levels PV1 and PV2.

In the embodiment described in FIG. 6, the steps S611 to S614 and the steps S621 to S634 may not be performed consecutively but also separately performed. That is, if memory cells are previously programmed based on a specific target voltage, the steps S621 to S634 may be performed at any time when the non-volatile memory operates. For example, after memory cells are programmed with PV1, PV2, and PV3 based on data, memory cells having threshold voltages of PV1−α to PV1+α, PV2−α to PV2+α, and PV3−α to PV3+α are selected in an idle period of the non-volatile memory using the method of steps S621 and S622, and the selected memory cells are further programmed using the method described at steps S631 to S634.

In accordance with the present invention, after a general program operation is completed, a verify operation for selecting/detecting under-programmed memory cells is performed, and the program operation is performed on the selected memory cells again.

Thus, no under-programmed memory cell exists in the non-volatile memory, and accordingly, the reliability of the non-volatile memory can be considerably increased.

While the present invention has been described with respect to the specific embodiments, it will be apparent to those skilled in the art that various changes and modifications may be made without departing from the spirit and scope of the invention as defined in the following claims.

What is claimed is:

1. An operating method of a non-volatile memory device, comprising:
programming a plurality of memory cells based on a target voltage level;
verifying threshold voltage levels of the plurality of memory cells based on a correction voltage level higher than the target voltage level and selecting a memory cell programmed lower than the correction voltage level among the memory cells; and
programming the selected memory cell based on the correction voltage level.

2. The method of claim 1, wherein the programming of the plurality of memory cells based on the target voltage level comprises:
applying a program voltage to the plurality of memory cells;
verifying threshold voltage levels of the plurality of memory cells based on the target voltage level; and
increasing the program voltage by a set level and applying the increased program voltage to a memory cell selected in the verification.

3. The method of claim 1, wherein the programming of the detected memory cell based on the correction voltage level comprising:
applying a program voltage to the detected memory cell;
verifying threshold voltage levels of the plurality of memory cells based on the correction voltage level; and
increasing the program voltage by a set level and applying the increased program voltage to a memory cell selected in the verification.

4. The method of claim 1, wherein the programming of the memory cells based on the target voltage level and the programming of the detected memory cell based on the correction voltage level are performed using an incremental step pulse program (ISPP) method, and an incremental step of a pulse program voltage applied in the programming based on the correction voltage level is smaller than that in the programming based on the target voltage level.

5. A method for operating a non-volatile memory device, comprising:
programming a plurality of memory cells based on a target voltage level;
reading the plurality of memory cells based on a first correction voltage level lower than the target voltage level and a second correction voltage level higher than the target voltage level; and
programming a memory cell of which a threshold voltage is higher than the first correction voltage level and lower than the second correction voltage level, among the plurality of memory cells, based on the second correction voltage level.

6. The method of claim 5, wherein the programming of the memory cells based on the target voltage level and the programming of the memory cell based on the second correction voltage level are performed using an incremental step pulse program (ISPP) method, and an incremental step of a pulse program voltage applied in the programming based on the second correction voltage level is smaller than that in the programming based on the target voltage level.

7. A non-volatile memory device comprising:
a plurality of memory cells; and
at least one circuit configured to program the plurality of memory cells,
wherein the at least one circuit is configured to program the plurality of memory cells based on a target voltage level, verify threshold voltage levels of the plurality of memory cells based on a first correction voltage level higher than the target voltage level, select a memory cell programmed lower than the first correction voltage level among the memory cells, and program the selected memory cell based on the first correction voltage level.

8. The non-volatile memory device of claim 7, wherein the at least one circuit is configured to read the plurality of memory cells based on the first correction voltage level and a second correction voltage level lower than the target voltage level and program a memory cell of which a threshold voltage is higher than the second correction voltage level and lower than the first correction voltage level, among the plurality of memory cells, based on the first correction voltage level.
